(19) United States
(12) Patent Application Publication
(10) Pub. No.: US 2013/0256627 A1
(43) Pub. Date: Oct. 3, 2013

(54) Sensors Incorporating Freestanding Carbon NanoStructures

(71) Applicants: Himanshu Jain, Bethlehem, PA (US); Venkataraman Swaminathan, Bridgewater, NJ (US); Jiri Cech, Bethlehem, PA (US)

(72) Inventors: Himanshu Jain, Bethlehem, PA (US); Venkataraman Swaminathan, Bridgewater, NJ (US); Jiri Cech, Bethlehem, PA (US)

(73) Assignee: LEHIGH UNIVERSITY, Bethlehem, PA (US)

(21) Appl. No.: 12/490,484

(22) Filed: Jun. 24, 2009

(51) Int. Cl. H01L 31/028; H01L 31/18

(52) U.S. Cl. CPC H01L 31/028; H01L 31/1804
USPC 257/9; 438/57

(57) ABSTRACT

Sensors for detecting IR radiation, UV radiation, X-Rays, light, gas, and chemicals. The sensors herein incorporate freestanding carbon nanostructures, such as single-walled carbon nanotubes (“SWCNT”), atomically thin carbon sheets having a thickness of about between 1 atom and about 5 atoms (“graphene”), and combinations thereof. The freestanding carbon nanostructures are suspended above a substrate by a plurality of conductors, each conductor electrically connected to the carbon nanostructure. In one method of manufacture, a resonance chamber is formed under the carbon nanostructure by etching of the substrate, yielding a sensor wherein the resonance chamber is bounded by at least the substrate and the carbon nanostructure.

### STATEMENT REGARDING FEDERALLY SPONSORED RESEARCH

This invention was made with government support under Contract No. W911NF-07-2-0064 respectively awarded by the Department of Defense—U.S. Army Research Lab (ARL). The government may have certain rights in the invention.

### FIELD OF INVENTION

Sensors for detecting IR radiation, UV radiation, X-Rays, light, gas, and chemicals. The novel sensors herein incorporate freestanding carbon nanostructures, such as single-walled carbon nanotubes (“SWCNT”), atomically thin carbon sheets (including those having a thickness of about between 1 atom and about 5 atoms commonly known as “graphene”), and combinations thereof.

### BACKGROUND

There is a pressing need for new sensors of low energy, low intensity radiation. The advanced cameras, sensors and imaging techniques find applications not only in astronomy, but also in security, military, medical and biological applications. With a continuing need to detect radiation with wavelength as high as 100 μm, there exists the need for sensitive bolometers with fast and accurate response.

Recently, extremely large photoresponse was reported for suspended single-walled carbon nanotube (SWCNT) films (See H. Jerominek, F. Picard, D. Vincent, Vanadium oxide films for optical switching and detection, Optical Engineering 32 (1993) 2092-2099) which makes them an attractive candidate for the sensitive element of an infrared (IR) bolometer and microbolometer focal plane arrays. Optical properties of SWCNT networks, including photoconductivity, suggest outstanding potential for application in nanoscale optoelectronics. See H. Jerominek, T. D. Pope, M. Renaud, N. R. Swart, F. Picard, M. Lehoux, S. Savard, G. Bilodeau, D. Audet, L. N. Phong, C. N. Qiu, 64 64, 128 128 and 240 320 pixel uncooled IR bolometric sensor arrays, Proceedings of SPIE 3061 (1997) 236-247. For example, conventional micro-bolometer with thin film absorber, fabricated by e-beam lithography. See M. Moreno et al., J. Non-Cryst. Solids (2008), doi:10.1016/j.jnoncrysol.2007.09.116 (in press) has a volume of 10×0.2×0.05=0.1 μm³. By replacing metal with carbon nanotube network, one should be able to reduce this volume by 3-4 orders. See A. Naemee et al. ACM Proc., San Diego, 568-573 (2007).

The sensitivity of detection among different living species that rely on detecting heat/IR radiation, such as the fire-seeking beetles (Melanophila acuminate), has been estimated to be approximately 60 μW/cm². See M. E. Itkis, et al, Science 21 Apr. 2006: Vol. 312. no. 5772, pp. 413-416. That is significantly better than the IR sensors available today. Thin films of SWCNT have shown bolometric response time as short as 50 ms. The extremely fast bolometric response of a freestanding network is expected to be 5-10 orders more sensitive to IR intensity than the previously reported photoresponse of network on substrates, where the main limitation is ultrafast relaxation time of photocarriers (10⁻¹⁰ to 10⁻¹⁴ s). See, P. V. Avramov, P. B. Sorokin, A. S. Fedorov, D. Fedorov, Y. Maeda, Phys. Rev. B 74, 245417 (2006). For the latter, bolometric response is obviously limited by thermal coupling to substrate. In this regard, note that the prominent features in the optical spectra of SWCNT have been widely attributed to inter-band transitions associated with series of van Hove singularities in the one-dimensional (1D) density of states. See U. Dettlaff, V. Skakalova, J. C. Meyer, J. Cech, B. Mueller, and S. Roth. Effect of fluorination on electrical properties of single walled carbon nanotubes and C peapods in networks. Current Applied Physics 7, 42-46 (2007). However, recent studies suggest that the electron-hole pairs are strongly coupled in 1D lattice and that the major photoexcitations are excitons, rather than free carriers. Id. H. Jerominek 2092-2099, and H. Jerominek 236-247. The response of a CNT network for bolometric applications does not appear to be by free carriers photoconductivity for the following reasons: (i) The response is strongly decreased by thermal coupling to substrate or to environment, (ii) The time constant is typically 1-100 ms and (iii) Magnitude of bolometric response depends on the temperature derivative of resistance dR/dT. Finally, the absorption coefficient α of SWCNT is extremely high, (10³ to 10⁴ cm⁻¹) i.e. at least an order of magnitude greater that for HgCdTe. It also extends far to the low energy region, without much of a drop in performance. An absolute value of temperature coefficient of resistance (TCR) is at least as high as observed with conventional vanadium dioxide films.

### BRIEF STATEMENT

A sensor is provided for detecting IR radiation, UV radiation, X-Rays, light, gas, and chemicals. The sensors include: a substrate; a freestanding carbon nanostructure suspended between a plurality of conductors, each conductor electrically connected to the carbon nanostructure; and a resonance chamber, wherein the resonance chamber is bounded by at least the substrate and the freestanding carbon nanostructure.

A method is provided for manufacturing a sensor incorporating a freestanding carbon nanostructure. In one embodiment, the method includes the steps of: (a) providing a substrate comprising a multi-layered Si/SiO₂ chip; (b) generating a network of nanotubes on a selected exposed surface of the substrate using chemical vapor deposition (CVD); (c) providing conductors on the selected exposed surface of the substrate; and (d) removing at least a portion of the previously exposed selected substrate surface underlying the nanotube network to form a resonance chamber to yield a freestanding nanotube network that spans between at least two conductors to form a boundary of the resonance chamber; wherein the remainder of the chamber is bounded by any of the substrate, the conductors, and combinations thereof. Additional features may be understood by referring to the accompanying drawings, which should be read in conjunction with the following detailed description and examples

### BRIEF DESCRIPTION OF THE DRAWINGS

FIG. 1 shows a schematic drawing of an exemplary sensors and its method of fabrication in accordance with one embodiment herein.

FIG. 2 shows a Scanning Electron Microscope (SEM) image of a substantially uniform network of single-walled carbon nanotubes that is representative of a nanotube network in one embodiment herein.

FIG. 3 shows an elevational view of an exemplary sensor in accordance with another embodiment herein.

FIG. 4 shows an elevational view of exemplary sensor in accordance with yet another embodiment herein.

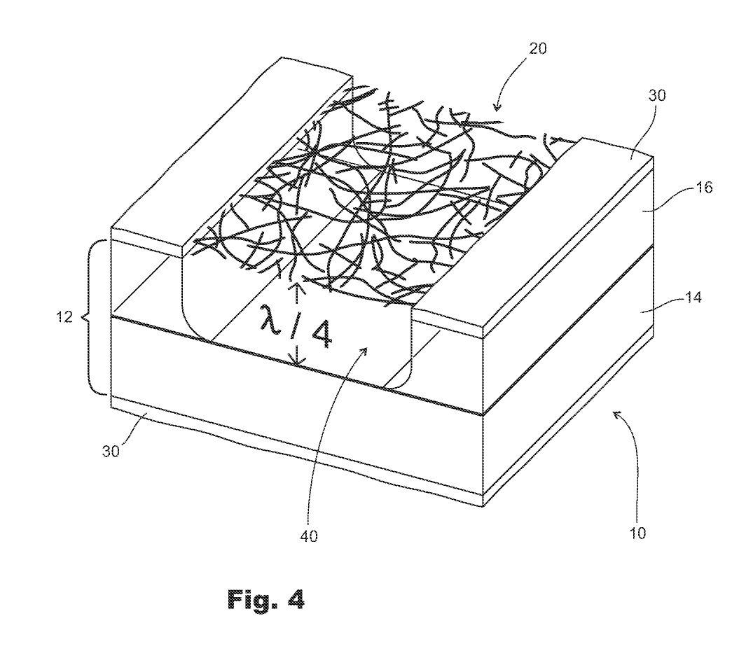

### DETAILED DESCRIPTION OF THE DRAWINGS

The novel sensors herein incorporate freestanding carbon nanostructures, such as single-walled carbon nanotubes (“SWCNT”), atomically thin carbon sheets (including those commonly known as graphene sheets and having a thickness of about between 1 atom and about 5 atoms (“graphene”)), and combinations thereof. For example, nanotube networks, and particularly SWCNT networks, can be a sensitive sensor of low energy radiation. Indeed, the inventors have conceived that a practical viability of such a nanotube network exists, both in terms of structure of an apparatus and methods of fabrication. The inventors have conceived of methods to build and operate novel sensors incorporating at least one thin suspended yet freestanding (relevant to a substrate) carbon nanostructure, such as a network of nanotubes, and/or a graphene sheet. In one embodiment, the carbon nanostructure includes a sparse, substantially uniform network of single walled carbon nanotubes (“SWCNT”). Additionally, the inventors have developed an understanding of the underlying mechanisms of the electrical response of a suspended SWCNT network to IR radiation and temperature.

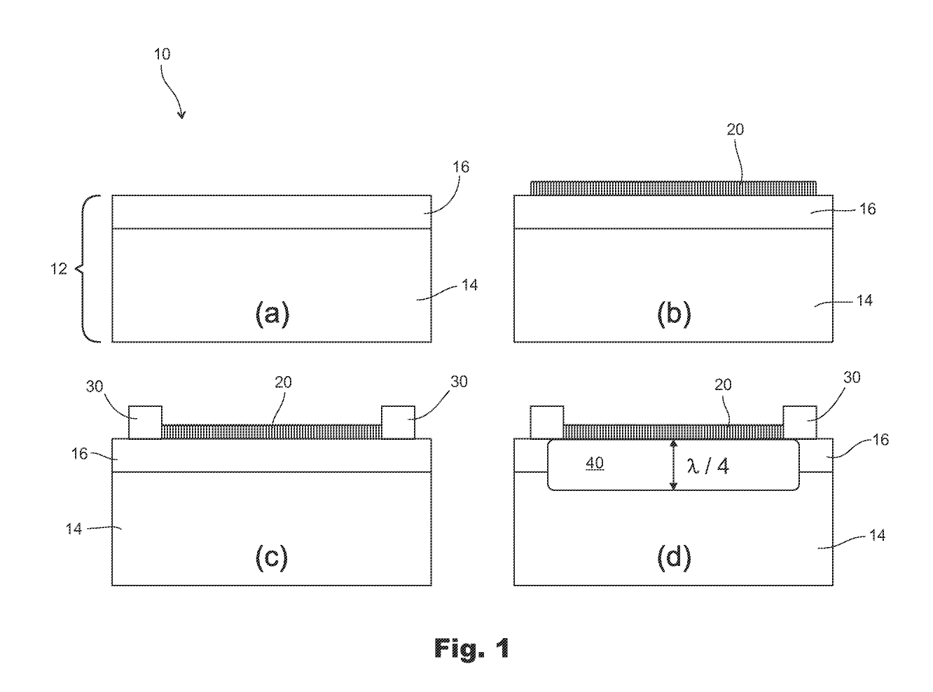

A first embodiment and design of the proposed sensor is shown in FIG. 1. That embodiment is based on established micro electromechanical system (MEMS) technology. For example, as shown in FIG. 1, the sensor 10 can be fabricated by employing a multiple-step fabrication process. In the embodiment shown in FIG. 1, the process involves the labeled steps of: (a) providing a substrate 12, such as a multi-layered Si/SiO₂ chip (base layer 14 comprising Si, and sacrificial layer 16 comprising an oxide of Si such as SiO₂) with spin coated Ni/Co compound catalyst; (b) generating a carbon nanostructure 20 such as a network of nanotubes on a selected exposed surface of the substrate 12, such as a SWCNT network grown using chemical vapor deposition (CVD); (c) providing conductors 30 on the exposed surface of the substrate 12, such as lithographically deposited electrical contacts in electrical contact with the network of nanotubes; and (d) removing at least a portion of the previously exposed selected substrate surface underlying the nanotube network to form a resonance chamber 40, such as by chemically underetching a portion of the substrate 12 (such as a portion of sacrificial layer 16) to yield a freestanding nanotube network that spans between at least two conductors 30 to form a boundary of the resonance chamber 40, the remainder of the chamber 40 being bounded by any of the substrate 12 (layers 14, 16), the conductors 30, and combinations thereof. The resonance chamber 40 enhances response, such as bolometric response, of the apparatus.

In a further embodiment, the method of fabricating the sensor 10 is provided as follows.

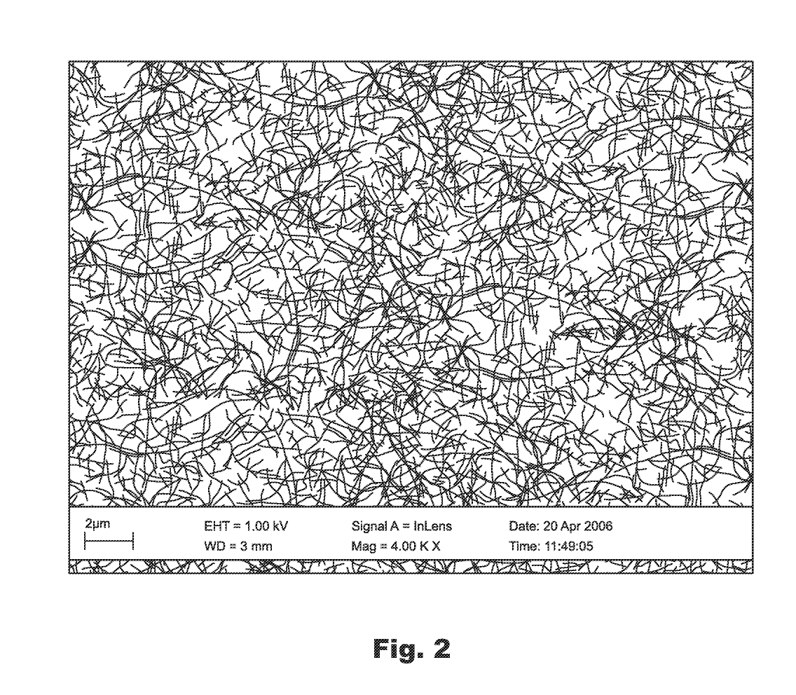

(a) The first step is the preparation of a sparse, CVD grown network of clean single walled nanotubes on a selected substrate 12, preferably a substrate 12 having a base layer 14 that is selected to be resistant to etching based on a selected etchant, such as HF. For example, the base layer may include Si, which is resistant to etching by HF. The substrate 12 further includes a sacrificial layer 16 overlying the base layer, the sacrificial layer selected to be susceptible to etching based on the selected etchant. For example, the sacrificial layer 16 may include SiO₂, which is susceptible to etchant HF. As generally described in references in J. A. Robinson, E. S. Snow, S. C. Badescu, T. L. Reinecke, and F. K. Perkisn. Role of defects in single-walled carbon nanotube chemical sensors. NANO LETTERS 6, 1747-1751 (2006), Infrared Sensor and Systems, E. L. Dereniak and G. D. Boreman, Wiley, New York (1996) p. 414., F. Niklaus, C. Jansson, A. Decharat, J. Kalhammer, H. Pettersson, and G. Stemme, Proc. SPIE 6542, 65421M (2007), which are hereby incorporated by reference, carrier gas (such as an argon/hydrogen mixture) is passed with vapor phase carbon feedstock through heated quartz tube placed in a moving tube furnace. A catalyst is provided, such as a spin-coated or evaporated organometallic compound or salt, or a plurality of such compounds. The carrier gas mixture is introduced to the bubbler with carbon feedstock. While the inventors conceive that a well-tuned carrier-feedstock-catalyst system can be operated even at atmospheric pressure, a reduced atmosphere will also produce desirable results. For example, using Ni/Co based catalyst deposited by spin coating, with ethanol as carbon source will provide a substantially uniform network of SWCNTs, as characteristically shown in FIG. 2, which is an SEM micrograph of a CVD grown nanotube network on chip (field enhancement of SWCNTs, actual diameter of tubes is much smaller, such as about 1-2 nm). Id. J. A. Robinson, 1747-1751. This process is useful not only for providing an individual bolometer by deposition on a single chip, but also for manufacturing of arrays having virtually identical microbolometers. Characterization of the SWCNT networks is accomplished by scanning electron microscope (SEM) with in-lens secondary electrons (SE) sensor.

(b) After synthesis of a carbon nanostructure 20 such as a SWCNT network or graphene sheet on a selected substrate 12 as described in step a above, such as silicon base substrate 14 with a SiO₂ sacrificial layer 16, conductors 30 such as gold or gold-palladium alloy readout contacts are provided. The conductors 30 can be provided by known methods such as conventional or e-beam lithography. In one example, conductors 30 are provided using spin-coated PMMA as a photoresist and sputtering/evaporation as contact deposition technique. It is desirable to next characterize electrical parameters of contacted networks, while still on the substrate 12, and before the next fabrication step, to verify the desired performance of the carbon nanostructure 20 in concert with the conductors 30 connected to the nanostructure 30.

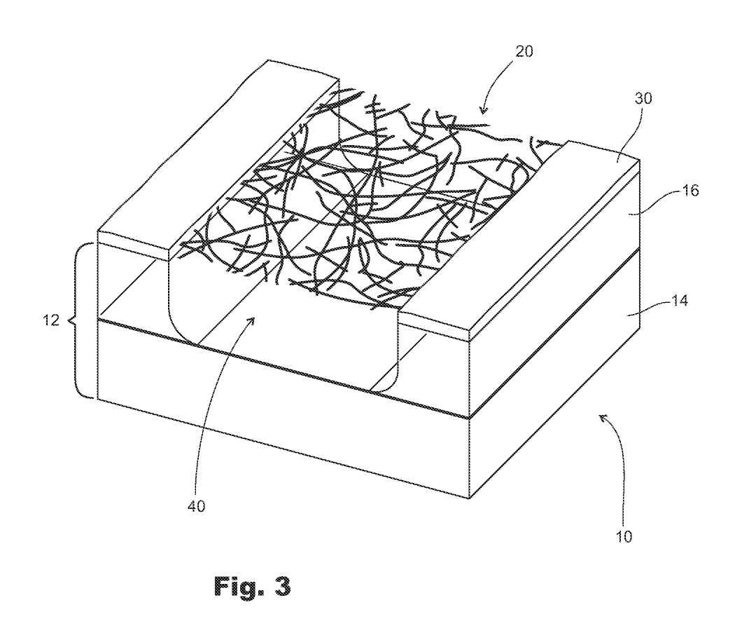

(c) The next fabrication step involves underetching the resonator (also referred to as a cavity or resonance chamber 40 herein) under the carbon nanostructure 20. For example, that will yield a freely suspended carbon nanostructure 20, such as nanotube network. For example, as shown in FIG. 3, underetched, freestanding nanotubes are provided wherein metal contacts are approx. 300 nm wide. Ideally, such chamber 40 should have depth of ¼ of design wavelength (λ). For example, acceptable chambers 40 can be formed by using dilute HF as the etchant in combination with a sacrificial layer 16 comprising SiO₂. Where a deeper cavity is desired that extends through the sacrificial layer 16 and into the base substrate 14, warm KOH is selected as an etchant for a base substrate 14 comprising Si. Both etchants are compatible with conductors 30 (such as gold and other electrically conductive materials) and in particular with SWCNT networks. The etchant(s) should be selected so as not to undesirably alter the SWCNT or other carbon nanostructure 20 network, such as by undesirable functionalization and/or chemical damage.

(d) Upon completion of etching step c above, such as while the apparatus 10 is still in the etchant liquid, a drying step is performed. For example, a supercritical drying step is desirable in order to avoid damage to the subtle MEMS (micro-electrical mechanical system) structure, such as by undesirable surface tension of a moving liquid-vapor interface.

Upon completion of the above steps, the apparatus 10 is characterized by the presence of freestanding carbon nanostructures 20 suspended over a resonance chamber 40. The depth of the chamber 40 is controllable by selection of etchant(s) and etching methods and times, and can be monitored by scanning electron microscope (SEM) for example, to check shape and depth of prepared chamber 40. For example, the next step may involve making contacts between the conductors 30 and other electrical leads on the chip carrier, and the bonding pads. Alternatively, the flip-chip process for making electrical contacts can be used.

Further, evaluation of the fabrication process and the resulting apparatus 1, such as bolometers, can be evaluated. For example, one can measure electro-optical response of prepared devices, employing lock-in amplifier to record the amplitude of the voltage oscillation on the load resistance in a standard dc bias circuit. The load resistance should be maintained at or close to the value of SWCNT sample for maximum detection efficiency. By way of further example, IR radiation will be modulated by chopper to provide desired levels for detection.

One goal is to provide an IR sensor that meets or exceeds bolometers that are known in nature and in science. For example, the sensitivity of detection among different living species that rely on detecting heat/IR radiation, such as the fire-seeking beetles (Melanophila acuminate), has been estimated to be approximately 60 μW/cm². The “average” SWCNT (assuming the diameter of (10,10), (8,8) and (12,0) tubes) has 136 carbon atoms per nm. Assuming 50 um wide contacts, with ˜10 nanotubes per 1 um, we expect 500 tubes per contact. We multiply it by the length of the gap (in nm), say 30 um, to give 2.04e9 carbon atoms, which would weigh 4.06-14 grams. Assuming worst case scenario, the heat capacity could be 3k_{B}/(mass of C atom in gm) ˜2078 mJ/gK, we obtain heat capacity of 8.4e-14 J/K for the whole network. However, if we use experimentally reported heat capacity for graphite at room temperature (710 mJ/gK), the heat capacity of our sample network would be 2.88e-14 J. For MWCNTs C ˜720 mJ/gK is found, which is nearly identical to the value for graphite. Note that heat capacity of MWCNTs agrees with that of graphite above the crossover temperature (˜80K) from 2D to 3D phonon behavior. That is significantly better than the IR sensor available today. By comparison, macroscopic freestanding SWCNT networks described herein are expected to show sensitivity to 0.12 μW with sample of 3.5×0.5 mm, which should give an improvement by approximately one order of magnitude (6.85 μW/cm²).

By way of further example, single-walled carbon nanotubes (SWCNT) are expected to provide very desirable IR detection properties when incorporated into the apparatus described herein. The inventors continue to investigating various freestanding single-walled carbon nanotube (SWCNT) networks for the detection of mid- and far-IR radiation. Suspended SWCNT ribbons exhibit extremely large bolometric response over a wide temperature range, including room temperature. Thus, SWCNT network is an ideal candidate for developing a low cost uncooled IR sensor. Recently, devices based on individual tubes have shown promising results not only in photodetection but also in multiple sensor applications (e.g. chemical, biological agents). However, they are extremely difficult to mass-produce reliably, because each individual nanotube is different. Scaled-up production of such devices can be impossible. The inventors approached this long-felt need by employing a uniform, sparse network of SWCNT, which is then electrically contacted, characterized and under-etched to form an active freestanding, conductor-suspended SWCNT region with high bolometric response. Statistical response of such a freestanding suspended SWCNT network should be comparable to that of individual nanotubes that exhibit very high absorption coefficient, but will be more consistent, predictable and reliable. Moreover, a significant advantage is that the methods herein will permit production of large array of such active devices (pixels) on a single substrate with minimal fabrication steps as compared to known methods, thereby providing an efficient focal plane array (FPA). Such FPAs should be able to operate at room temperature with comparable or better sensitivity than the current vanadium oxide based FPAs.

In one embodiment, provided herein is an uncooled infrared (IR) sensor based on single-walled carbon nano tubes (SWCNT) in a novel design. The key feature of the device is a sparse network of freestanding SWCNT film as the IR sensing element, which is connected to electrical resistance measuring component via metal pads. Primarily due to extremely small thermal mass and other unusual properties of SWCNTs, and further due to fewer and simpler processing steps in fabricating a focal plane array (FPA), the proposed device is expected to provide significantly superior performance and lower cost compared to current state-of-the-art uncooled IR FPAs. The key advantages of the proposed IR sensor are summarized in Table 1 below.

TABLE 1

| | Performance Criterion | Improvements over current technology |
|---|---|---|
| 1 | Sensitivity (R* C_{TCR}) | ++ (significant improvement) |
| 2 | Detectivity D* (1/G) | ~ (comparable or better) |
| 3 | Time constant τ (C/G) | +++ (dramatic improvement) |
| 4 | Manufacturability and Cost | + (significant improvement) |

Key =
R: electrical resistance of each pixel.
C_{TCR}: thermal coefficient of electrical resistance.
G: thermal conductance of each pixel and associated structure.
C: heat capacity.

Evaluation of the Key Characteristics of the Sensors. The inventors have provided an evaluation of an embodiment of the sensor employing single walled carbon nanotube as an IR Sensor. The evaluation of the key parameters pertaining to the performance of the proposed single walled carbon nano tube (SWCNT) uncooled IR sensors is summarized below.

Sensitivity. The sensitivity of a resistive bolometer in measuring a temperature change, ΔT, is given by its temperature coefficient of resistance, C_{TCR}. The sensitivity or change in electrical resistance due to a unit change in temperature is given by:

ΔR/ΔT˜R_{T}_{₀}C_{TCR}

where R_{T0} is the base resistance. A high value of C_{TCR}, therefore, implies high sensitivity. At present for the state-of-the-art uncooled bolometers the materials of choice are vanadium dioxide (VO₂), and amorphous Si. Vanadium dioxide based materials exhibit fairly high TCR, typically 0.02 to 0.025/K. For the a-Si based devices, TCR values in the range 0.028 to 0.043/K have been reported as seen in Table 2. Comparisons of TCR at 350K versus length for a SWCNT, MWCNT and copper wires are available. Although higher TCR values can be obtained with VOₓ (x>2), it is not preferred since the reproducibility of such films is problematic.

TABLE 2
The results of a recent study of a-Si based thermo-sensing layers;
comparison of the characteristics of micro-bolometers.

| | | | Pixel | Pixel | Voltage |
|---|---|---|---|---|---|
| Thermo- | Eₐ | TCR, α | area, A_{b} | resistance, | responsivity, |
| sensing layer | (eV) | (K⁻¹) | (μm²) | R_{b} (Ω) | R_{U} (V W⁻¹) |
| a-Si:H,B | 0.22 | 0.028 | 48 × 48 | 3 × 10⁷ | 10⁶ |
| a-SiₓGe_{y}:H | 0.34 | 0.043 | 70 × 66 | 1 × 10⁵ | 2 × 10^{5a} |
| a-SiₓGe_{y}B_{z}:H | 0.21 | 0.027 | 70 × 66 | 1 × 10⁶ | 2.8 × 10^{5a} |
| a-SiₓGe_{y}:H | 0.34 | 0.043 | 70 × 66 | 5 × 10⁸ | 7.2 × 10^{5a} |

| | Current | | | |
|---|---|---|---|---|
| | res- | Spectral | | |
| Thermo- | ponsivity | response | Detectivity, D^{a} | |
| sensing layer | R_{I} (A/W) | (μm) | (cm Hz^{1/2}W⁻¹) | |
| a-Si:H,B | — | 5-14 | — | |
| a-SiₓGe_{y}:H | 0.3-14 | 2-14 | 4 × 10⁹ ± 1 × 10⁹ | Sandwich |
| | | | | structure |
| a- | 2.6 × 10⁻² | 2-14 | 5.9 × 10⁹ ± 3.6 × 10⁸ | Planar |
| SiₓGe_{y}B_{z}:H | | | | structure |
| a-SiₓGe_{y}:H | 2 × 10⁻³ | 2-14 | 7 × 10⁹ ± 3.3 × 10⁸ | Planar |
| | | | | structure |

^{a}Voltage responsivity R_{U}, was calculated from the current responsivity R_{I}.

The TCR for SWCNT reported by different authors varies greatly presumably due to the presence of unknown percentages of metallic and semiconducting tubes. Recently, theoretical estimates were made using a bundle of tubes with graphene-like properties, giving TCR=0.005-0.007/K at 350K, depending on length, as shown on FIG. 1. However, Itkis et al. in a recent Science article reported TCR values between 1 and 2.5% (0.01-0.025/K) for as grown SWNT film in the 330 to 100 K temperature range. These values are comparable to that of vanadium dioxide. If metallic tubes are selectively eliminated from the SWCNT network, for example by preferential Joule heating, the TCR of remaining semiconducting network will be significantly enhanced. Furthermore, if we dope SWNCT with Si, the bandgap and, hence TCR, can be further increased in a controlled manner. Additionally, chemical functionalization of the network can enhance desirable properties and eliminate undesirable properties depending upon the desired use and performance of the network and apparatus.

The inventors believe that the TCR of SWCNT can be increased also by reducing the film thickness, modifying the processing conditions, and by chemical functionalization of the tubes whereby we modify the inter-tube contacts. For example, depending on the nature of functionalized layer, the probability of tunneling, and thus the value of TCR may double for a 10% change in energy barrier. Therefore, the inventors expect that the TCR values would be at least as good as that of currently used VO₂, but potentially several times higher with the predominantly semiconducting network. Further, the R_{T0} of SWCNT can be significantly higher than that of VOₓ, giving rise to additional improvements in the sensitivity. It was shown that relatively simple room temperature chemical modifications of network can change its conductance by 2 orders. Thus, while the existing SWCNTs have shown TCR comparable to that of VOₓ, further improvements can be realized for the reasons outlined above. We anticipate conservatively that x2 improvement can be achieved in the sensitivity.

Detectivity, D*. In the limit of temperature fluctuation noise, the D* of a thermal sensor is inversely proportional to the square root of G where G is the thermal conductance. For the radiation limit, assuming sensor can radiate only on one side, the theoretical maximum for G ˜4×10⁻⁹ W/K. This yields a maximum D* at room temperature of ˜2*10¹⁰ cm Hz^{1/2} W⁻¹ compared to currently achievable values in the range ˜(4-7)×10⁹ cm Hz^{1/2} W⁻¹. G is the total thermal conductance between the bolometer and its surrounding consisting of several components. Heat may dissipate to the surroundings through the SWCNT base legs or gas atmosphere, by radiation, and by gas convection. In most practical cases, the thermal conduction through the bolometer legs will dominate the overall loss. For a VO_{X} bolometer operated in a vacuum, G is estimated to be ˜3.7×10⁻⁸ W/K. Although SWCNTs are predicted to have high thermal conductance, we expect that in an FPA configuration the thermal conductance of the sensor will be determined by the relatively low value of the pads. Assuming that the thermal isolation legs between pixels would be similar to those designed for VOₓ bolometers, the G value of the SWCNT would be comparable. As a result, D* values of SWCNT bolometer FPA would be comparable or higher (owing to a higher TCR as noted in Sec 1) than that of VO_{X} FPAs.

Thermal time constant (τ). One of the issues with a thermal bolometer is the residual memory between frames. It is important that the heat from a scene imaged onto the pixel in one frame must essentially conduct away before the heat in the next frame can be detected. Otherwise, residual memory from the previous frame smears the image if the scene changes. The thermal time constant of a bolometer, given by C/G where C is thermal capacity, determines the residual memory effect. In general, τ should be about ⅓ the frame time such that the memory effect is minimal. For VOₓ C is ˜4.34×10⁻¹⁰ J/K and for G ˜3.7×10⁻⁸ W/K, τ=12 msec. Using the ⅓ rule, this gives ˜30 Hz frame rate typical of most commercial bolometer FPAs. The volume and mass (thus heat capacity) of the SWCNT absorber are a few orders of magnitude smaller than the current VOx thin film devices. Assuming worst-case-scenario we estimate a value of 8.4×10⁻¹⁴ J/K for SWCNT, which is lower by ˜4 orders of magnitude compared to VOx. For the same G, we would then expect a time constant in the order of microseconds, resulting in a frame rate of the order of MHz! Under practical conditions, we may expect frame rates of several to 100's of kHz with SWCNT bolometers. This orders of magnitude improvement in fast imaging of the infrared scene would greatly expand the application domain of the proposed bolometers, especially for situational awareness that require high temporal resolution.

Manufacturing and cost. The fabrication of current VOₓ based two-level FPAs requires as many as 15-25 steps See R. R. Neli, I. Doi, J. A. Diniz, and J. W. Swart. Development of process for far infrared sensor fabrication. SENSORS AND ACTUATORS A-PHYSICAL, 132, 400-406 (2006) and S. Franssila. Introduction to Microfabrication. WILEY-V C H VERLAG GMBH, 2004, involving sacrificial layers, complex film deposition, lithography, and other costly processes. By comparison, our exploratory work indicates that the proposed fabrication of SWCNT bolometers is very simple. It would include growing SWCNT network, depositing readout contacts and etching out oxide substrate. Thus the manufacturing of the new devices is expected to be much less complex, with better reproducibility, resulting in substantial cost advantages as well. The ability to fabricate finer features in SWCNT than in VOₓ films would allow smaller pixel size or higher pixel density in the former material, resulting in higher image resolution.

Summary of expected benefit of SWCNT bolometers. SWCNT based bolometers are expected to have sensitivity and detectivity comparable but potentially higher than with the current VOₓ based FPAs. SWCNT based bolometer FPAs would enable dramatically higher frame rate (˜kHz) operation, which would be suitable for fast imaging applications requiring high temporal resolution. SWCNT based bolometers are expected to be less expensive since our process has fewer lithographic steps and is much less complex. Finally, since we can obtain uniform sparse network across the whole substrate, pixel size can be scaled down to increase the total number of pixels as well as pixel density significantly.

While this description is made with reference to exemplary embodiments, it will be understood by those skilled in the art that various changes may be made and equivalents may be substituted for elements thereof without departing from the scope. In addition, many modifications may be made to adapt a particular situation or material to the teachings hereof without departing from the essential scope. Also, in the drawings and the description, there have been disclosed exemplary embodiments and, although specific terms may have been employed, they are unless otherwise stated used in a generic and descriptive sense only and not for purposes of limitation, the scope of the claims therefore not being so limited. Moreover, one skilled in the art will appreciate that certain steps of the methods discussed herein may be sequenced in alternative order or steps may be combined. Therefore, it is intended that the appended claims not be limited to the particular embodiment disclosed herein.

We claim:

1. A sensor comprising; a substrate; a freestanding nanocarbon structure suspended between a plurality of conductors, each conductor electrically connected to the nanocarbon structure; and a resonance chamber, wherein the resonance chamber is bounded by at least the substrate and the freestanding nanocarbon structure.

2. The sensor of claim 1, wherein the nanocarbon structure comprises at least one of single-walled carbon nanotubes and graphene.

3. The sensor of claim 2, wherein the substrate comprises an intermediate sacrificial layer and a base layer, wherein the intermediate sacrificial layer is located between the nanocarbon structure and the base layer of the substrate.

4. The sensor of claim 2 wherein the depth of the resonance chamber is selected in relation to a radiation wavelength (λ).

5. The sensor of claim 2 wherein at least a portion of the nanocarbon structure is separated from the substrate layer by the resonance chamber.

6. The sensor of claim 2 wherein the resonance chamber boundaries comprise the nanocarbon structure and the substrate.

7. The sensor of claim 6 wherein the chamber boundaries further comprise at least one of the conductors, the intermediate sacrificial layer; or the substrate.

8. The sensor of claim 2 wherein the base substrate comprises materials suitable for substrate use in lithographic processes.

9. The sensor of claim 8, wherein the material suitable for substrate use in lithographic processes comprises Si.

10. The sensor of claim 9, wherein the intermediate sacrificial substrate comprises at least one oxide of Si.

11. A method of manufacturing the sensor of claim 1, the method comprising the steps of: a) providing a substrate; b) generating a nanocarbon structure on at least one selected exposed surface of the substrate; c) connecting the nanocarbon structure to at least two conductors; and d) forming the resonance chamber by underetching at least a portion of the substrate surface underlying the carbon structure.

12. The method of claim 11, wherein the carbon nano structure comprises at least one of single-walled carbon nanotubes and graphene.

13. The method of claim 12, wherein the substrate comprises an intermediate sacrificial layer and a base layer, wherein the intermediate layer is located between the carbon nanostructure and the base layer of the substrate.

14. The method of claim 12 wherein the depth of the resonance chamber is selected in relation to a radiation wavelength (λ).

15. The method of claim 12 wherein at least a portion of the carbon nanostructure is separated from the substrate layer by the resonance chamber.

16. The method of claim 12 wherein the resonance chamber boundaries comprise the carbon nanostructure and the substrate.

17. The method of claim 16 wherein the chamber boundaries further comprise at least one of the conductors, the intermediate sacrificial layer; or the substrate.

18. The method of claim 17 wherein the network of nanotubes extends between the plurality of conductors.

19. The method of claim 12 wherein the base substrate comprises materials suitable for substrate use in lithographic processes.

20. The method of claim 19, wherein the material suitable for substrate use in lithographic processes comprises Si.

21. The method of claim 20, wherein the intermediate sacrificial substrate comprises at least one oxide of Si.

22. A method of manufacturing the sensor of claim 1, comprising the steps of (a) providing a substrate comprising a multi-layered Si/SiO₂ chip; (b) generating a network of nanotubes on a selected exposed surface of the substrate using chemical vapor deposition (CVD); (c) providing conductors on the selected exposed surface of the substrate; and (d) removing at least a portion of the previously exposed selected substrate surface underlying the nanotube network to form a resonance chamber to yield a freestanding nanotube network that spans between at least two conductors to form a boundary of the resonance chamber; wherein the remainder of the chamber is bounded by any of the substrate, the conductors, and combinations thereof.
